(19) United States
(12) Patent Application Publication
(10) Pub. No.: US 2004/0016997 A1
(43) Pub. Date: Jan. 29, 2004

(54) Socket for semiconductor package

(75) Inventor: Tomohiro Ushio, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/349,025

(22) Filed: Jan. 23, 2003

(30) Foreign Application Priority Data
Jul. 24, 2002 (JP) 2002-215425

(51) Int. Cl. H01L 23/02

(52) U.S. Cl. 257/678

(57) ABSTRACT

A socket for semiconductor package in which most portion of a package side electrode portion of a contact pin has an inclined portion inclined at a predetermined angle with respect to a vertical direction, and when a land grid array package is received in a housing, a contact end of the package side electrode portion abuts on the land electrode within the area of the land electrode, and when the land grid array package is lowered, the contact end slides on the surface of the land electrode to remove foreign matters adhering to the land electrode to thereby put the contact end into contact with the land electrode at a good contact pressure.

### BACKGROUND OF THE INVENTION

1. Field of the Invention

The present invention relates to a socket for semiconductor package that is used for electrically connecting a semiconductor package such as a land grid array package to a package board such as a printed wiring board.

2. Description of the Related Art

FIG. 14 is a partial cross-sectional view to show a socket for semiconductor package in the prior art. In FIG. 14, a reference symbol 1 denotes a socket for semiconductor package, 2 denotes a semiconductor package received in the socket for semiconductor package, 2a denotes an array shaped package electrode of the semiconductor package 2, 3 denotes a housing for receiving the semiconductor package 2, 4 denotes a base constituting a bottom wall of the housing 3, 5 denotes a frame constituting a side wall of the housing 3, 5a denotes a locking protrusion provided on one side of the frame 5, 6 denotes a contact pin fixed to the base 4 in a vertical direction, 6a denotes a board side electrode portion of the contact pin 6, 6b denotes a package side electrode portion of the contact pin 6, 7 denotes a support plate fixed to the housing 3 on a side opposite to the locking protrusion 5a, 8 denotes a support shaft provided on a top portion of the support plate 7, 9 denotes a cover one end of which is supported by the support shaft 8, 10 denotes a pressing part that is provided on a bottom surface of the cover 9 and presses a back surface of the semiconductor package 2, 11 denotes a support shaft provided on the other end of the cover 9, 12 denotes a locking member supported by the support shaft 11, and 12a denotes a locking protrusion engaged with the locking protrusion 5a of the frame 5.

Next, an operation will be described.

When the semiconductor package 2 is inserted into the frame 5 of the housing 3 with the package electrode 2a faced down, the package electrode 2a of the semiconductor package 2 is put into contact with the package side electrode portion 6b of the contact pin 6. When the cover 9 is closed in this state, the pressing part 10 presses the back surface of the semiconductor package 2 to bring the package electrode 2a into press contact with the package side electrode portion 6b. Then, when the cover 9 is closed to a final position, the locking protrusion 12a of the locking member 12 is engaged with the locking protrusion 5a of the frame 5, whereby the cover 9 is locked by the housing 3.

Since the socket for the semiconductor package in the prior art is constituted in the manner described above and the package side electrode portion of the contact pin is extended in a vertical direction from a top surface of the base of the housing, the package electrode of the semiconductor package is put into contact with the package side electrode portion of the contact pin always at a constant position. For this reason, in a case where a foreign matter such as an oxide film comes out to be adhered on the package electrode, there is presented a problem that the package electrode is not put into good contact with the package side electrode portion.

### SUMMARY OF THE INVENTION

The present invention has been made to solve the problem described above, and an object of the present invention is to provide a socket for semiconductor package that can put a package electrode of the semiconductor package into good contact with a package side electrode portion of a contact pin.

The socket for a semiconductor package in accordance with the present invention is characterized in that most portion of the package side electrode portion is formed into an inclined portion inclined at a predetermined angle with respect to a vertical direction and a contact end of the package side electrode portion is made to abut on the package electrode within an area of the package electrode when the semiconductor package is received in the housing.

Therefore, in accordance with the present invention, it is possible to produce an effect that an action of lowering the semiconductor package caused by an action of closing a cover, makes the contact end of the package side electrode portion abutting on a surface of the package electrode to thereby enable a removing of foreign matters adhering to the surface of the package electrode. Further, since the action of lowering the semiconductor package increases a bending of the inclined portion, it is possible to produce an effect of putting the package electrode into contact with the package side electrode portion at a good contact pressure.

Moreover, the socket for a semiconductor package in accordance with the present invention is characterized in that: a plurality of lead wires are interposed between the board side electrode portion and the package side electrode portion; a slider is provided in the housing movably in a horizontal direction; the board side electrode portion is fixed to the housing; the package side electrode portion is fixed to the slider; and a contact end of the package side electrode portion is made to abut on the package electrode within an area of the package electrode when the semiconductor package is received in the housing.

Therefore, in accordance with the present invention, it is possible to produce an effect of putting the package electrode into contact with the package side electrode portion at a good contact pressure. Moreover, it is possible to produce an effect of sliding the contact end on the surface of the package electrode to remove foreign matters adhering to the surface of the package electrode by moving the slider.

### BRIEF DESCRIPTION OF THE DRAWINGS

FIG. 1 is a partial cross sectional view to show a socket for semiconductor package in accordance with an embodiment 1 of the present invention.

FIG. 2 is a cross sectional view of a land grid array package.

FIG. 3 is a partial enlarged view of FIG. 1.

FIG. 4 is a partial cross sectional view to show a state where the land grid array package is inserted into the socket for the semiconductor package.

FIG. 5 is a partial enlarged view to show a state where a land electrode abuts on a package side electrode portion.

FIG. 6 is a cross sectional view taken along a line A-A in FIG. 5.

FIG. 7 is a diagram that corresponds to FIG. 5 and shows a state where the package side electrode portion slides.

FIG. 8 is a diagram that corresponds to FIG. 6 and shows a state where the package side electrode portion slides.

FIG. 9 is a partial cross sectional view to show a state where a cover is closed.

FIG. 10 is a partial cross sectional view to show the socket for the semiconductor package in accordance with an embodiment 2 of the present invention.

FIG. 11 is a transverse cross sectional view of a base.

FIG. 12 is a partial cross sectional view to show a state where the land grid array package is inserted into the socket for the semiconductor package.

FIG. 13 is a partial cross sectional view to show a state where the cover is closed.

FIG. 14 is a partial cross sectional view to show the socket for the semiconductor package in the prior art.

### DETAILED DESCRIPTION OF THE PREFERRED EMBODIMENTS

The preferred embodiments of the present invention will be described below.

Embodiment 1

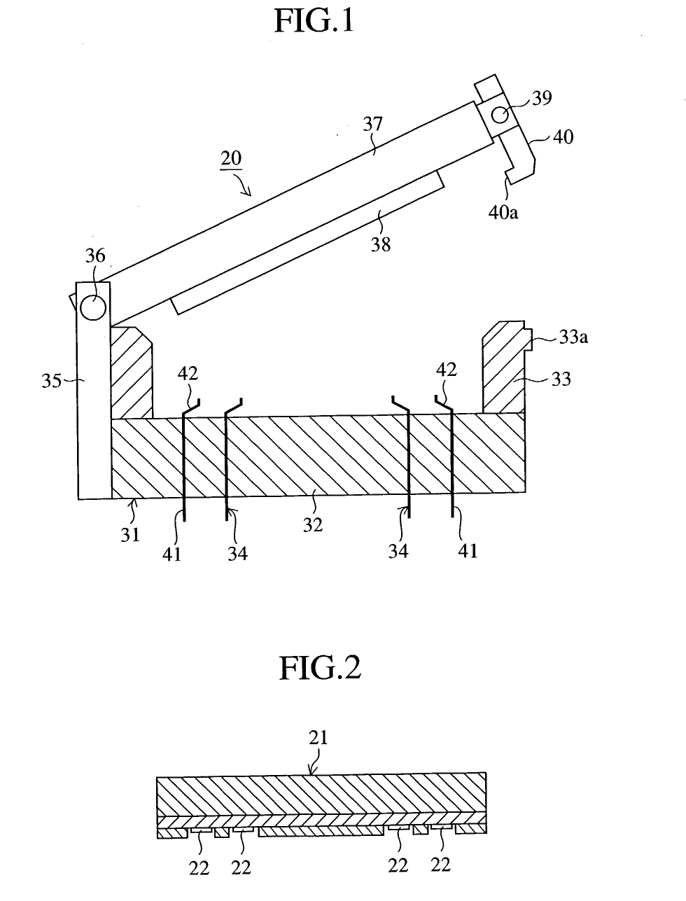

FIG. 1 is a partial cross sectional view to show a socket 20 for semiconductor package in accordance with an embodiment 1 of the present invention. FIG. 2 is a cross sectional view of a land grid array package (semiconductor package) 21 received in the socket 20 for the semiconductor package. The land grid array package 21 has a plurality of circular land electrodes (package electrodes) 22 arranged in an array.

In the socket 20 for the semiconductor package, a reference symbol 31 denotes a housing packaged on a package board (not shown) such as a printed wiring board, 32 denotes a base (bottom wall) constituting a bottom wall of the housing 31, 33 denotes a frame constituting a side wall of the housing 31, 33a denotes a locking protrusion provided on one side of the frame 33, 34 denotes contact pins which are fixed to the base 34 in a vertical direction and the number of which corresponds to the number of land electrodes 22, 35 denotes a support plate fixed to a side of the housing 31 on a side opposite to the locking protrusion 33a, 36 denotes a support shaft provided on an upper end portion of the support plate 35, 37 denotes a cover one end of which is supported by the support shaft 36, 38 denotes a pressing part that is provided on a bottom surface of the cover 37 and presses a back surface of the land grid array package 21, 39 denotes a support shaft provided on the other end of the cover 37, 40 denotes a locking member that is supported by the support shaft 39 and locks the cover 37 to the housing 31, and 40a denotes a locking protrusion that is provided on a lower portion of the locking member 40 and can be engaged with the locking protrusion 33a of the frame 33.

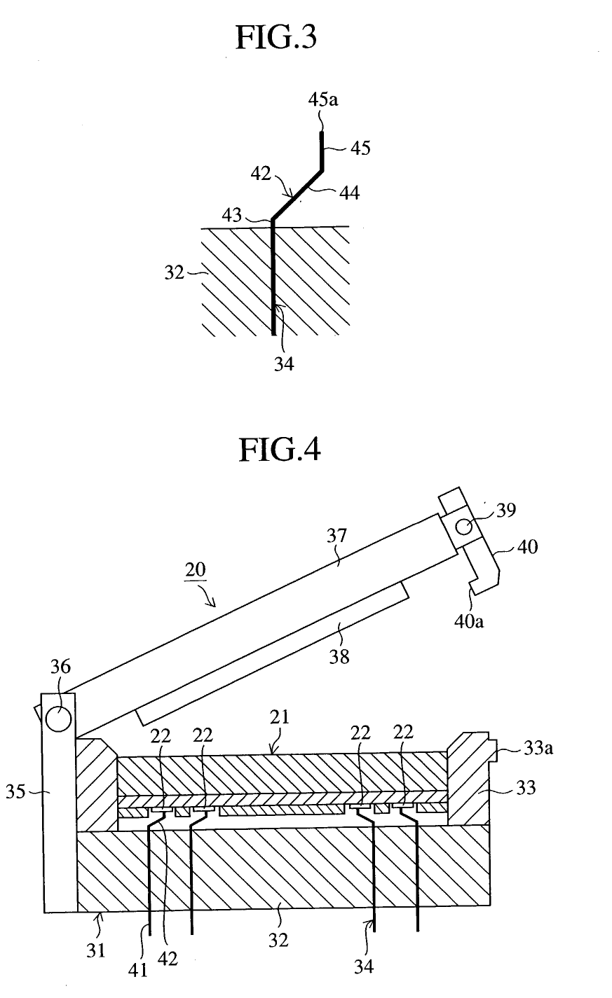

At this point, the contact pin 34 includes a board side electrode portion 41 which is extended downward from the bottom surface of the base 32 and connected to a board electrode of the package board and a package side electrode portion 42 which is extended upward from the top surface of the base 32 and to which the land electrode 22 of the land grid array package 21 is connected. Moreover, as shown in a partial enlarged view in FIG. 3 the package side electrode portion 42 has a lower side vertical portion 43 extended upward vertically from the top surface of the base 32, an inclined portion 44 extended upward at a given inclined angle from the top end of the bottom side vertical portion 43, and an upper side vertical portion 45 extended upward vertically from the top end of the inclined portion 44. A tip of the upper side vertical portion 45 is a contact end 45a to be put into contact with the land electrode 22. Then, the given inclined angle of the inclined portion 44 is an angle that the land electrode 22 makes the contact end 45a sliding on the land electrode 22 within the area of the land electrode 22 when the land electrode 22 is lowered.

Here, the contact pin 34 is made of a conductive material and has flexibility as a whole, but an actually bent portion of the contact pin 34 is limited to a portion protruding from the base 32. Thus, in order to ensure a good contact pressure between the land electrode 22 and the contact end 45a, it is desirable that lengths of the lower side vertical portion 43 and the upper side vertical portion 45 are made as short as possible to bend only the inclined portion 44 when the contact end 45a is pressed down by the land electrode 22.

Next, an operation will be described.

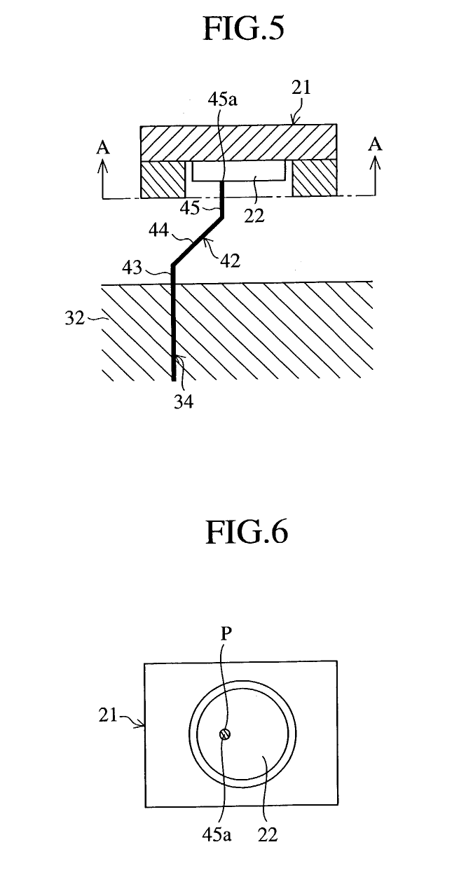

As shown in FIG. 4 when the land grid array package 21 is inserted into the frame 33 with the land electrode 22 faced down in a state where the cover 37 is opened, as shown in FIG. 5 and FIG. 6 the land electrode 22 abuts on the package side electrode portion 42 of the contact pin 34 to thereby bring a state where the land grid array package 21 is supported by all the package side electrode portions 42. At this time, the contact end 45a of the package side electrode portion 42 abuts on the land electrode 22 at a position P closer to its left side in the drawing.

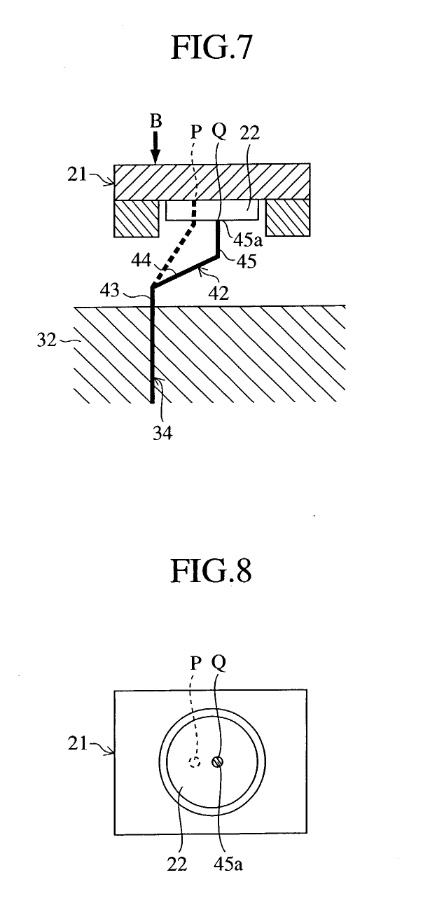

When the cover 37 is closed in this state, the pressing part 38 becomes to press down the land grid array package 21. Then, as shown in FIG. 7 and FIG. 8 as the land grid array package 21 is lowered in a direction shown by an arrow B, the upper side vertical portion 45 is made lowered and the inclined portion 44 is inclined clockwise in the drawing around a portion connected to the lower side vertical portion 43. At this time, the package side electrode portion 42 is deformed from a state shown by a broken line to a state shown by a solid line such that the contact end 45a slides on the surface of the land electrode 22 from the position P to a position Q. Thus, the contact end 45a removes foreign matters adhering to the land electrode 22 while it slides. Moreover, since the inclined portion 44 is deformed heavily to increase its resilient force, the contact end 45a contacts with the land electrode 22 at a good contact pressure.

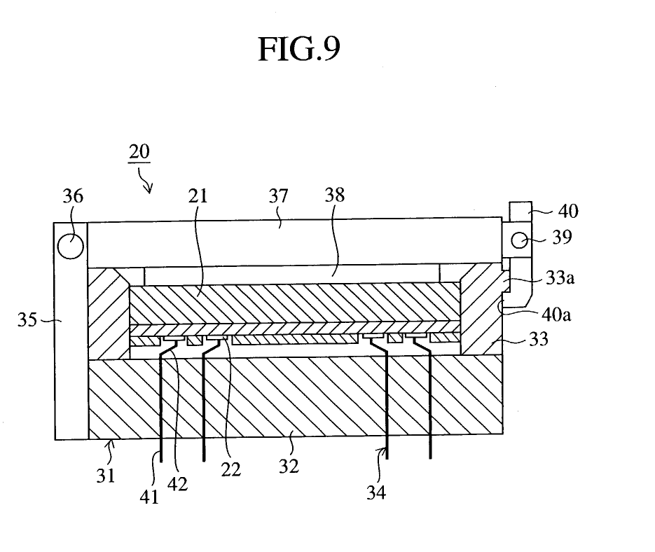

Then, as shown in FIG. 9 when the cover 37 is closed finally, the locking protrusion 40a of the locking member 40 is engaged with the locking protrusion 33a of the frame 33. In this manner, the cover 37 is locked by the housing 31 to keep a good contact pressure between the land electrode 22 and the package side electrode portion 42.

As described above, according to the embodiment 1 since the inclined portion 44 of the package side electrode portion 42 is inclined at the predetermined angle when the contact end 45a is pressed by the land electrode 22, it is possible to produce an effect that the contact end 45a slides on the surface of the land electrode 22 to remove foreign matters adhering to the land electrode 22 such as an oxide film. Moreover, when the contact end 45a is pressed by the land electrode 22, the inclined portion 44 is deformed heavily to increase its resilient force, so it is possible to produce an effect of putting the contact end 45a into contact with the land electrode 22 at good contact pressure.

Embodiment 2

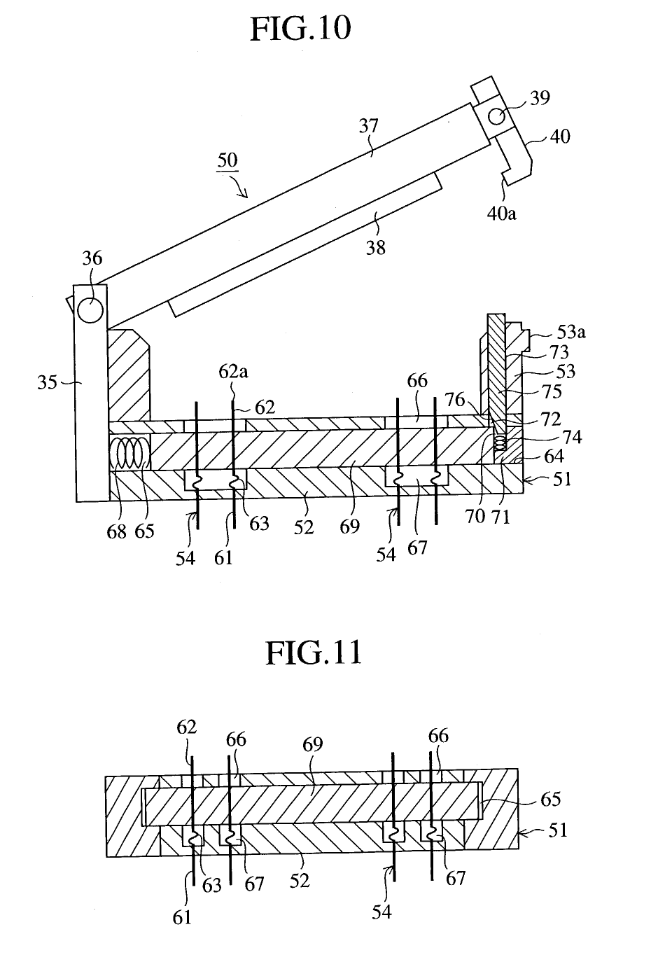

FIG. 10 is a partial cross sectional view to show a socket 50 for the semiconductor package in accordance with an embodiment 2 of the present invention. The same parts as used in the embodiment 1 are denoted by the same reference symbols and their further descriptions will be omitted. In FIG. 10, a reference symbol 51 denotes a housing packaged on a package board (not shown) such as a printed wiring board, 52 denotes a base (bottom wall) constituting a bottom wall of the housing 51, 53 denotes a frame constituting a side wall of the housing 51, 53a denotes a locking protrusion provided on one side of the frame 53, and 54 denotes a plurality of contact pins provided on the base 52 in a vertical direction.

At this point the contact pin 54 includes a board side electrode portion 61 extended downward from a bottom surface of the base 52 and connected to a board electrode of the package board, a package side electrode portion 62 extended upward from a top surface of the base 52 and connected to the land electrode 22 of the land grid array package 21, and a lead wire 63 for connecting the board side electrode portion 61 to the package side electrode portion 62. A top end of the package side electrode portion 62 is a contact end 62a contacting the land electrode 22.

FIG. 11 is a transverse cross sectional view of the base 52. In the base 52 are formed a space 65 having an opening 64, a window 66 for enabling the package side electrode portion 62 of the contact pin 54 to move, and a groove 67 for enabling the lead wire 63 to move. A compression coil spring (urging member) 68 and a slider 69 are fitted in this order in the space 65 and the opening 64 is closed by a closing member 71 having a groove 70. Moreover, a hole 72 and a hole 73 both of which communicate with the groove 70 of the closing member 71 are formed in the base 52 and the frame 53, respectively. A compression coil spring (urging member) 74 is arranged in the groove 70 of the closing member 71. A wedge member 75 is inserted into the hole 72 of the base 52 and the hole 73 of the frame 53, respectively, and its bottom portion is inserted into the groove 70 of the closing member 71. On the lower portion of the wedge member 75 is formed an inclined surface 76 abutting on a right end of the slider 69, so that when the wedge member 75 is lowered, the wedge member 75 moves the slider 69 to left in the drawing.

Then, the board side electrode portion 61 of the contact pin 54 is fixed to the base 52 within an area of the groove 67 and the package side electrode portion 62 of the contact pin 54 is fixed to the slider 69 within an area of the window 66. At this time, in order to ensure a sufficient contact pressure between the land electrode 22 and the package side electrode portion 62, the package side electrode portion 62 is protruded upward with an appropriate length from the top surface of the base 52. Moreover, until the land grid array package 21 is received in the housing 51, the slider 69 is urged by the compression coil spring 68 to an initial position on a right side in the drawing, that is, to a position closer to a right side within the area of the land electrode 22 where the contact end 62a of the package side electrode portion 62 contacts the land electrode 22 when the land grid array package 21 is received in the housing 51.

Next, an operation will be described.

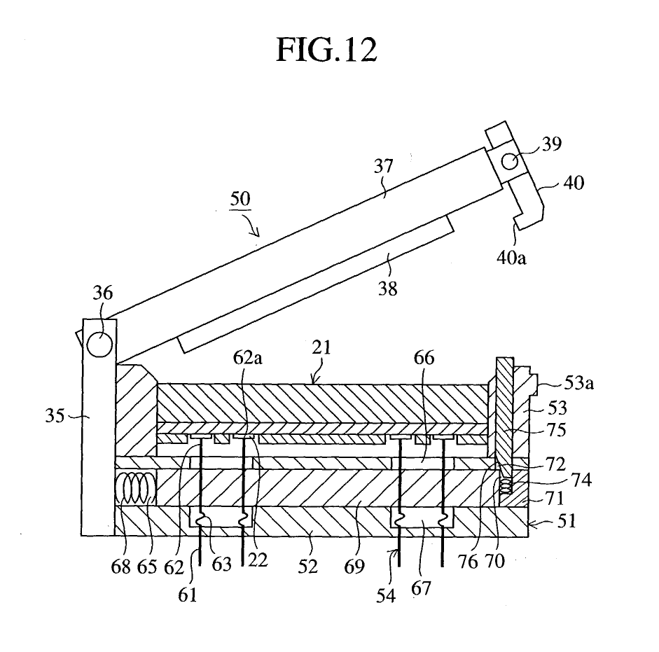

As shown in FIG. 12 in a state where the cover 37 is opened, the slider 69 is urged to the initial position and the wedge member 75 is urged upward by a resilient force of the compression coil spring 74. When the land grid array package 21 is inserted into the frame 53 with the land electrode 22 faced down in this state, the land electrode 22 of the land grid array package 21 abuts on the contact end 62a of the package side electrode portion 62 to bring a state where the land grid array package 21 is supported by all the package side electrode portions 62. At this time as described above the contact end 62a abuts on the land electrode 22 at the position closer to its right side.

When the cover 37 is closed in this state, the pressing part 38 presses the land grid array package 21 and the cover 37 presses down the wedge member 75. This moves down the wedge member 75 against the resilient force of the compression coil spring 74 and thus the inclined surface 76 of the wedge member 75 moves the slider 69 to left against a resilient force of the compression coil spring 68. At the same time, as the slider 69 is moved, the contact end 62a is slid to left on the surface of the land electrode 22 to remove foreign matters adhering to the land electrode 22.

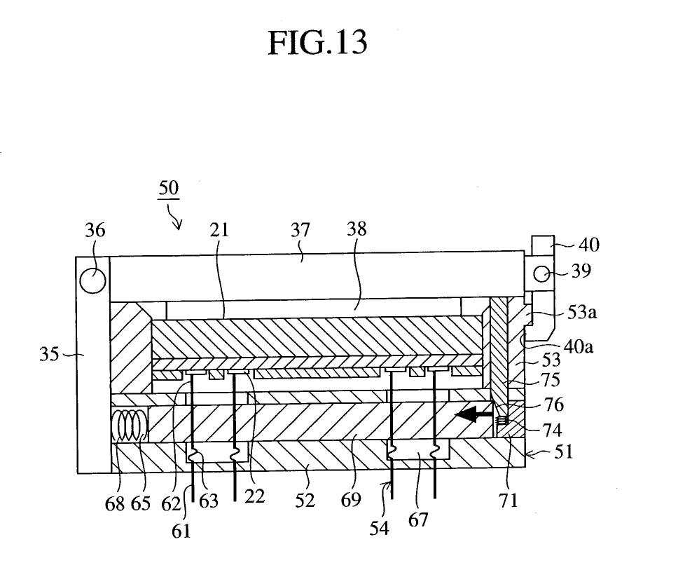

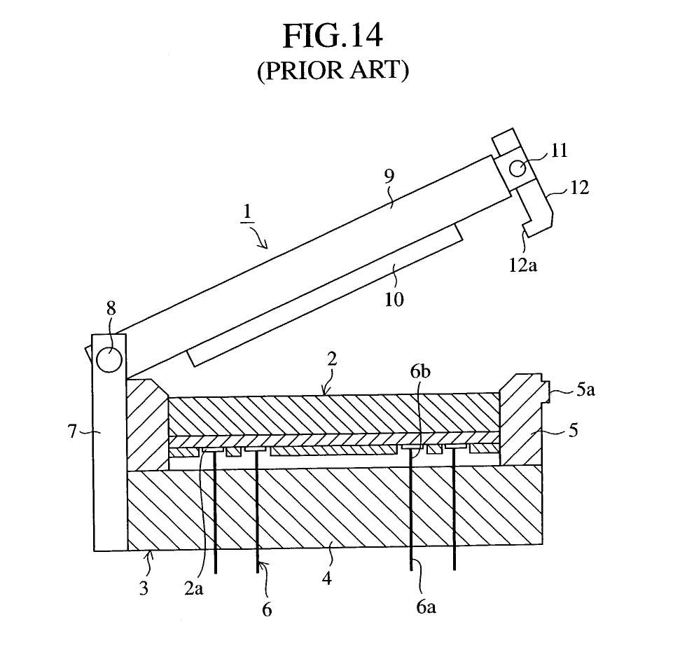

Then, as shown in FIG. 13 the locking protrusion 40a of the locking member 40 is engaged with the locking protrusion 53a of the frame 53 when the cover 37 is closed finally. In this manner, the cover 37 is locked by the housing 51 to keep a good contact pressure between the land electrode 22 and the package side electrode portion 62.

As described above, according to the embodiment 2 because the slider 69 is automatically moved and the contact end 62a is slid on the surface of the land electrode 22 when the cover 37 is closed, so that it is possible to produce an effect of removing foreign matters adhering to the land electrode 22. Moreover, since the package side electrode portion 62 is made straight, it is possible to produce an effect of using a conventional contact pin.

Incidentally, while the cases where the sockets 20, 50 for the semiconductor package correspond to the land grid array package 21 have been described in the embodiments 1, 2 described above, the above mentioned constitution can be applied similarly even to a case where the sockets 20, 50 for the semiconductor package correspond to a ball grid array package in place of the land grid array package.

What is claimed is:

1. A socket for semiconductor package comprising:
a housing for receiving a semiconductor package and packaged on a package board;
a plurality of contact pins provided in the housing such that they electrically connect a plurality of package electrodes of the semiconductor package to a plurality of board electrodes of the package board, respectively, each of the contact pins having a board side electrode portion that is extended downward from a bottom wall of the housing to be connected to the board electrode and a package side electrode portion that is extended upward from a bottom wall of the housing to be connected to the package electrode; and
a cover provided openably and closably on the housing for pressing the semiconductor package received in the housing, wherein
most portion of the package side electrode portion is formed into an inclined portion inclined at a predetermined angle with respect to a vertical direction, and a contact end of the package side electrode portion is made to abut on the package electrode within an area of the package electrode when the semiconductor package is received in the housing.

2. The socket for a semiconductor package as claimed in claim 1, wherein the predetermined angle is an angle that slides the contact end on the package electrode within the area of the package electrode by an action of lowering the semiconductor package caused by an action of closing the cover.

3. The socket for a semiconductor package as claimed in claim 1, wherein the package side electrode portion has a short vertical portion at a tip end of the inclined portion.

4. The socket for a semiconductor package as claimed in claim 3, wherein the package side electrode portion has a short vertical portion at a base end of the inclined portion.

5. A socket for semiconductor package comprising:
a housing for receiving a semiconductor package and packaged on a package board;
a plurality of contact pins provided in the housing such that they electrically connect a plurality of package electrodes of the semiconductor package to a plurality of board electrodes of the package board, respectively, each of the contact pins having a board side electrode portion that is extended downward from a bottom wall of the housing to be connected to the board electrode and a package side electrode portion that is extended upward from a bottom wall of the housing to be connected to the package electrode; and
a cover provided openably and closably on the housing for pressing the semiconductor package received in the housing, wherein
a plurality of lead wires are interposed between the board side electrode portion and the package side electrode portion,
a slider is provided in the housing movably in a horizontal direction,
the board side electrode portion is fixed to the housing,
the package side electrode portion is fixed to the slider, and
a contact end of the package side electrode portion is made to abut on the package electrode within an area of the package electrode when the semiconductor package is received in the housing.

6. The socket for a semiconductor package as claimed in claim 5, further comprising cooperatively moving means for moving the slider in accordance with an action of closing the cover.

7. The socket for a semiconductor package as claimed in claim 6, wherein the cooperatively moving means is a wedge member having an inclined surface abutting on one end of the slider.

8. The socket for a semiconductor package as claimed in claim 7, wherein the slider is urged to an initial position by an urging member.

9. The socket for a semiconductor package as claimed in claim 1, wherein the semiconductor package is a land grid array package or a ball grid array package.

10. The socket for a semiconductor package as claimed in claim 5, wherein the semiconductor package is a land grid array package or a ball grid array package.
